(19) United States
(12) Patent Application Publication
(10) Pub. No.: US 2022/0336426 A1
(43) Pub. Date: Oct. 20, 2022

(54) DRIVING SUBSTRATE, LIGHT EMITTING DEVICE AND MANUFACTURING METHOD THEREOF

(71) Applicant: BOE TECHNOLOGY GROUP CO., LTD., Beijing (CN)

(72) Inventors: Xiaoyan Zhu, Beijing (CN); Xinhong Lu, Beijing (CN); Jinnv Liu, Beijing (CN)

(73) Assignee: BOE TECHNOLOGY GROUP CO., LTD., Beijing (CN)

(21) Appl. No.: 17/760,627

(22) PCT Filed: May 18, 2021
(86) PCT No.: PCT/CN2021/094241

§ 371 Date: Mar. 15, 2022

(30) Foreign Application Priority Data
Jun. 19, 2020 (CN) 202010566468.2

(51) Int. Cl. H01L 25/075; H01L 33/62

(52) U.S. Cl. CPC H01L 25/0753; H01L 33/62; H01L 2933/0066

(57) ABSTRACT

Provided are a driving substrate, a light emitting apparatus and a manufacturing method therefor, which relate to the technical field of display. According to the present disclosure, a rigid substrate, a debonding layer, a first buffer layer, an organic material layer, a second buffer layer and a wiring layer are sequentially arranged in layer configuration in a component disposing area and a circuit board binding area, and the first buffer layer, an overlapping electrode layer, the organic material layer and the second buffer layer are sequentially arranged in layer configuration in a bending area. Two ends of the overlapping electrode layer respectively extend to the component disposing area and the circuit board binding area, and the wiring layer of the component disposing area and the wiring layer of the circuit board binding area are respectively connected to the overlapping electrode layer through via holes.

### CROSS REFERENCE TO RELEVANT APPLICATIONS

The present disclosure claims the priority of the Chinese patent application filed on Jun. 19^{th}, 2020 before the Chinese Patent Office with the application number of 202010566468.2 and the title of “DRIVING SUBSTRATE, LIGHT EMITTING DEVICE AND MANUFACTURING METHOD THEREOF”, which is incorporated herein in its entirety by reference.

### TECHNICAL FIELD

The present disclosure relates to the technical field of display technology, and particularly relates to a driving substrate, a light emitting apparatus and a manufacturing method therefor.

### BACKGROUND

In order to adapt to the development trend of light weight and thinness of a display, a micro-LED (including Micro LED and Mini LED) technology appears after a liquid crystal display (LCD). The major advantage of the micro-LED technology lies in the achievement of splicing, that is, a certain number of small-sized driving substrates are adopted to achieve super large size display.

### SUMMARY

The present disclosure provides a driving substrate, a light emitting apparatus and a manufacturing method therefor.

The present disclosure provides a driving substrate including a component disposing area, a circuit board binding area and a bending area located between the component disposing area and the circuit board binding area;

the driving substrate located in the component disposing area and the circuit board binding area includes a rigid substrate, a debonding layer, a first buffer layer, an organic material layer, a second buffer layer and a wiring layer which are sequentially arranged in layer configuration;

the driving substrate located in the bending area includes the first buffer layer, an overlapping electrode layer, the organic material layer and the second buffer layer which are sequentially arranged in layer configuration;

wherein two ends of the overlapping electrode layer respectively extend to the component disposing area and the circuit board binding area, and the wiring layer of the component disposing area and the wiring layer of the circuit board binding area are respectively connected to the overlapping electrode layer through via holes.

Optionally, the wiring layer includes a first wiring layer formed on the second buffer layer in the component disposing area and the circuit board binding area;

wherein the first wiring layer in the component disposing area is connected to one end of the overlapping electrode layer through a first via hole passing through the second buffer layer and the organic material layer; and the first wiring layer in the circuit board binding area is connected to the other end of the overlapping electrode layer through a second via hole passing through the second buffer layer and the organic material layer.

Optionally, the driving substrate located in the component disposing area and the circuit board binding area further includes a planarization layer covering the first wiring layer and the second buffer layer located in the component disposing area and the circuit board binding area.

Optionally, the driving substrate located in the component disposing area and the circuit board binding area further includes a third buffer layer covering the planarization layer, and the first wiring layer is partially exposed out of the planarization layer and the third buffer layer.

Optionally, a first opening passing through the third buffer layer and the planarization layer is formed in a position corresponding to the first wiring layer of the component disposing area, and the first opening is configured to connect light emitting components to the first wiring layer; and

a second opening passing through the third buffer layer and the planarization layer is formed in a position corresponding to the first wiring layer of the circuit board binding area, and the second opening is configured to connect a circuit board to the first wiring layer.

Optionally, the wiring layer further includes a second wiring layer formed on the planarization layer of the component disposing area, and the second wiring layer is connected to the first wiring layer through a third via hole passing through the planarization layer; and

the driving substrate located in the component disposing area and the circuit board binding area further includes a third buffer layer covering the planarization layer and the second wiring layer, and the second wiring layer is partially exposed out of the third buffer layer.

Optionally, a third opening passing through the third buffer layer is formed in a position corresponding to the second wiring layer in the component disposing area, and the third opening is configured to connect the light emitting components to the second wiring layer.

Optionally, an orthographic projection of the third opening on the rigid substrate overlaps with an orthographic projection of a top surface of the second wiring layer on the rigid substrate; or

the orthographic projection of the third opening on the rigid substrate is located within the orthographic projection of the top surface of the second wiring layer on the rigid substrate;

wherein the top surface of the second wiring layer is a surface of the second wiring layer away from the first wiring layer.

Optionally, the driving substrate located in the bending area further includes the debonding layer, and the debonding layer is located at a side, away from the overlaying electrode layer, of the first buffer layer.

Optionally, the driving substrate located in the bending area further includes the third buffer layer, and the third buffer layer is located at a side, away from the organic material layer, of the second buffer layer.

Optionally, when the bending area is in a non-bent state, the rigid substrate located in the component disposing area and the rigid substrate located in the circuit board binding area are disposed along a same horizontal plane; and

when the bending area is in a bent state, the rigid substrate located in the component disposing area is bonded to the rigid substrate located in the circuit board binding area.

Optionally, when the bending area is in the bent state, a bonding layer is disposed on a contact surface of the component disposing area and the bending area and a contact surface of the circuit board binding area and the bending area and between the rigid substrate located in the component disposing area and the rigid substrate located in the circuit board binding area.

Optionally, the debonding layer is made of polyimide or polyimide modified material; and a thickness of the debonding layer is 30 nm to 100 nm.

Optionally, the overlapping electrode layer is made of at least one of copper, molybdenum, titanium and aluminum; and a thickness of the overlapping electrode layer is 300 nm to 800 nm.

Optionally, a thickness of the first buffer layer is 50 nm to 300 nm; a thickness of the organic material layer is smaller than or equal to 6 μm; and a thickness of the second buffer layer is 50 nm to 300 nm.

The present disclosure also provides a light emitting apparatus, wherein the light emitting apparatus includes a circuit board, light emitting components and the driving substrate described above, the light emitting components are connected to the wiring layer in the component disposing area, and the circuit board is connected to the wiring layer in the circuit board binding area.

Optionally, the light emitting apparatus further includes a first adhesive layer disposed at a side, away from the rigid substrate, of the light emitting components and a second adhesive layer disposed on a side wall of the light emitting components;

wherein the first adhesive layer is configured to protect the light emitting components, and the second adhesive layer is configured to avoid a cross color of rays emitted by the light emitting components.

The present disclosure also provides a manufacturing method for a light emitting apparatus, wherein the method includes:

providing a base, wherein the base includes a rigid substrate, a debonding layer and a first buffer layer which are sequentially arranged in layer configuration; and dividing the base into a component disposing area, a circuit board binding area and a bending area located between the component disposing area and the circuit board binding area;

forming an overlapping electrode layer in the bending area of the base, wherein two ends of the overlapping electrode layer respectively extend to the component disposing area and the circuit board binding area;

forming an organic material layer covering the first buffer layer and the overlapping electrode layer;

forming a second buffer layer on the organic material layer;

forming a wiring layer on the second buffer layer in the component disposing area and the circuit board binding area; respectively connecting the wiring layer in the component disposing area and the wiring layer in the circuit board binding area to the overlapping electrode layer through via holes; and

removing the rigid substrate in the bending area.

Optionally, the step of forming the wiring layer on the second buffer layer in the component disposing area and the circuit board binding area includes:

respectively forming a first via hole and a second via hole passing through the second buffer layer and the organic material layer in the component disposing area and the circuit board binding area; and

forming a first wiring layer on the second buffer layer in the component disposing area and the circuit board binding area; and respectively connecting the first wiring layers to the overlapping electrode layer through the first via hole and the second via hole.

Optionally, after the step of forming the first wiring layer on the second buffer layer in the component disposing area and the circuit board binding area, the method further includes:

forming a planarization layer covering the first wiring layer and the second buffer layer located in the component disposing area and the circuit board binding area;

forming a second wiring layer on the planarization layer in the component disposing area; and connecting the second wiring layer to the first wiring layer through a third via hole passing through the planarization layer; and

forming a third buffer layer covering the planarization layer and the second wiring layer; and partially exposing the second wiring layer out of the third buffer layer.

Optionally, before the step of removing the rigid substrate in the bending area, the method further includes:

connecting light emitting components to the second wiring layer in the component disposing area, and connecting a circuit board to the first wiring layer in the circuit board binding area; and

forming a first adhesive layer at a side, away from the rigid substrate, of the light emitting components, and forming a second adhesive layer on a side wall of the light emitting components.

Optionally, the step of removing the rigid substrate in the bending area includes:

removing the rigid substrate and the debonding layer in the bending area by adopting a laser lift off process.

Optionally, after the step of removing the rigid substrate in the bending area, the method further includes:

disposing a bonding layer at a side, away from the debonding layer, of the rigid substrate, the side wall, facing the bending area, of the rigid substrate in the component disposing area and the side wall, facing the bending area, of the rigid substrate in the circuit board binding area; and

bending the bending area to ensure that the rigid substrate in the component disposing area is bonded to the rigid substrate in the circuit board binding area.

The above-mentioned description is only the summarization of technical solutions of the present disclosure. In order to know about the technical means of the present disclosure more clearly to achieve the purpose of implementation according to the content of the description and make the above-mentioned and other objectives, features and advantages of the present disclosure more obvious and comprehensible, specific implementation manners of the present disclosure will be described below.

### BRIEF DESCRIPTION OF THE DRAWINGS

In order to more clearly illustrate the technical solutions of the embodiments of the present disclosure or the prior art, the figures that are required to describe the embodiments or the prior art will be briefly introduced below. Apparently, the figures that are described below are embodiments of the present disclosure, and a person skilled in the art can obtain other figures according to these figures without paying creative work. It should be noted that the ratios in the drawings are merely illustrative and do not represent actual ratios.

FIG. 1 shows a schematic diagram of a structure of a relevant driving substrate;

FIG. 2 shows a schematic diagram of a structure of a driving substrate in an embodiment of the present disclosure;

FIG. 3 shows a schematic diagram of a structure of another driving substrate in an embodiment of the present disclosure;

FIG. 4 shows a schematic diagram of a structure of a light emitting apparatus in a non-bent state in a bending area in an embodiment of the present disclosure;

FIG. 5 shows a schematic diagram of a structure of a light emitting apparatus in a bent state in a bending area in an embodiment of the present disclosure;

FIG. 6 shows a flow chart of a manufacturing method for a light emitting apparatus in an embodiment of the present disclosure;

FIG. 7 shows a schematic diagram of a structure obtained after an overlapping electrode layer is formed on a base in an embodiment of the present disclosure;

FIG. 8 shows a schematic diagram of a structure obtained after an organic material layer and a second buffer layer are formed in an embodiment of the present disclosure;

FIG. 9 shows a schematic diagram of a structure obtained after a first wiring layer and a planarization layer are formed in an embodiment of the present disclosure;

FIG. 10 shows a schematic diagram of a structure obtained after a second wiring layer is formed in an embodiment of the present disclosure;

FIG. 11 shows a schematic diagram of a structure obtained after a third buffer layer is formed in an embodiment of the present disclosure;

FIG. 12 shows a schematic diagram of a structure obtained after light emitting components and a circuit board are connected to a wiring layer in an embodiment of the present disclosure; and

FIG. 13 shows a schematic diagram of a structure obtained after a first adhesive layer and a second adhesive layer are formed in an embodiment of the present disclosure.

### DETAILED DESCRIPTION OF THE EMBODIMENTS

In order to make the objects, features, and the advantages of the embodiments of the present disclosure clearer, the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

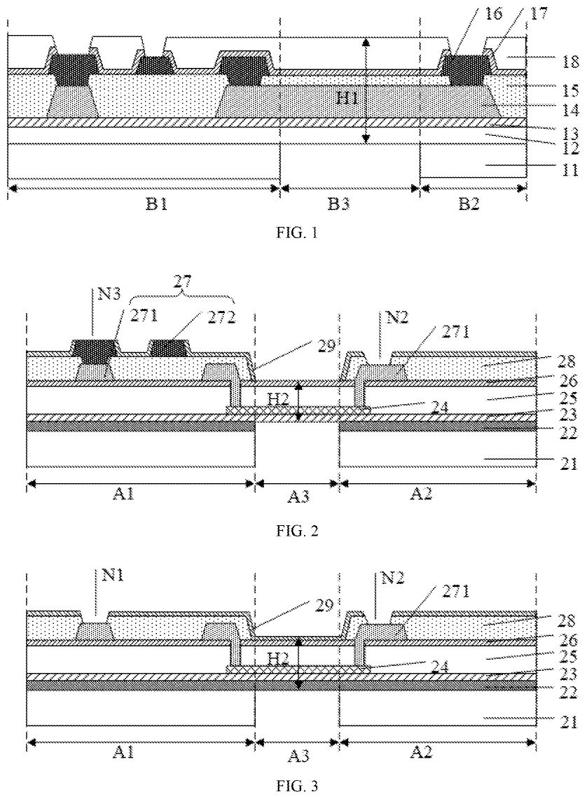

As shown in FIG. 1, a driving substrate in the related art includes a component disposing area B1, a circuit board binding area B2 and a bending area B3 located between the component disposing area B1 and the circuit board binding area B2; the driving substrate located in the bending area B3 includes an organic material layer 12, a buffer layer 13, a first wiring layer 14, a first planarization layer 15, a passivation layer 17 and a second planarization layer 18 which are sequentially arranged in layer configuration; and the driving substrate located in the component disposing area B1 and the circuit board binding area B2 includes a substrate 11, the organic material layer 12, the buffer layer 13, the first wiring layer 14, the first planarization layer 15, a second wiring layer 16, the passivation layer 17 and the second planarization layer 18 which are sequentially arranged in layer configuration.

Wherein, a thickness of the organic material layer 12 is 6 μm, a thickness of the buffer layer 13 is 0.1 μm, a thickness of the first wiring layer 14 is 2 μm, a thickness of the first planarization layer 15 is 1 μm, a thickness of the passivation layer 17 is 0.1 μm, and the thickness of the second planarization layer 18 is 6 μm. Found by the inventor, a thickness H1 of film layers in the bending area B3 is 15.2 μm, the maximum bending strain of an inorganic film layer in the bending area B3 is 4.73% greater than the safety bending strain 2.52% under the condition that the bending radius of the bending area B3 is 50 μm, if the bending area B3 is bent, fractures or cracks are easily caused in the inorganic film layer in the bending area B3, and then, the failure of the inorganic film layer in the bending area B3 occurs, so that the failure of the driving substrate is caused.

Therefore, in the embodiment of the present disclosure, by only disposing a first buffer layer, an overlapping electrode layer, an organic material layer and an second buffer layer in the bending area of the driving substrate, the number of the film layers in the bending area is reduced, so that the thickness of the film layers in the bending area is reduced, then, the maximum bending strain of the film layers in the bending area is reduced, it is ensured that fractures or cracks do not occur in the film layers in the bending area, the quality of the driving substrate is improved, and the bending reliability of the bending area is guaranteed.

FIG. 2 shows a schematic diagram of a structure of a driving substrate in an embodiment of the present disclosure. FIG. 3 shows a schematic diagram of a structure of another driving substrate in an embodiment of the present disclosure.

An embodiment of the present disclosure provides a driving substrate including a component disposing area A1, a circuit board binding area A2 and a bending area A3 located between the component disposing area A1 and the circuit board binding area A2; the driving substrate located in the component disposing area A1 and the circuit board binding area A2 includes a rigid substrate 21, a debonding layer 22, a first buffer layer 23, an organic material layer 25, a second buffer layer 26 and a wiring layer 27 which are sequentially arranged in layer configuration; the driving substrate located in the bending area A3 includes the first buffer layer 23, an overlapping electrode layer 24, the organic material layer 25 and the second buffer layer 26 which are sequentially arranged in layer configuration; wherein two ends of the overlapping electrode layer 24 respectively extend to the component disposing area A1 and the circuit board binding area A2, and the wiring layer 27 of the component disposing area A1 and the wiring layer 27 of the circuit board binding area A2 are respectively connected to the overlapping electrode layer 24 through via holes.

As shown in FIG. 2, in the bending area A3, the rigid substrate 21 and the debonding layer 22 are removed, the first buffer layer 23, the overlapping electrode layer 24, the organic material layer 25 and the second buffer layer 26 are only disposed in the bending area A3 of the driving substrate, and there are fewer film layers in the bending area A3, so that the thickness of the film layers in the bending area A3 is reduced, and then, the maximum bending strain of the film layers in the bending area A3 is reduced.

In the embodiment of the present disclosure, the first buffer layer 23 is made of silicon nitride, silicon oxide or silicon oxynitride, the thickness of the first buffer layer 23 is 50 nm to 300 nm, and the first buffer layer 23 is used for stopping water vapor from entering the driving substrate. Since the overlapping electrode layer 24 needs to be in a bent state later, in view of demands on the bending performance and stable voltage of the overlapping electrode layer 24, the overlapping electrode layer 24 may be made of at least one of copper, molybdenum, titanium and aluminum, for example, the overlapping electrode layer 24 may have a titanium/aluminum/titanium structure arranged in layer configuration, and the thickness of the overlapping electrode layer 24 is 300 nm to 800 nm, so that the overlapping electrode layer 24 may be normally bent, and it is ensured that the wiring resistance of the overlapping electrode layer 24 causes no influences on display; and the overlapping electrode layer 24 is used for connecting the component disposing area A1 to the circuit board binding area A2 to ensure that an electric signal between the component disposing area A1 and the circuit board binding area A2 may be normally transmitted. The organic material layer 25 is made of polyimide (PI), and the thickness of the organic material layer 25 is less than or equal to 6 μm. The second buffer layer 26 is made of silicon nitride, silicon oxide or silicon oxynitride, and the thickness of the second buffer layer 26 is 50 nm to 300 nm.

If the maximum thickness of each film layer in the bending area A3 is selected, that is, the maximum thickness 300 of the first buffer layer 23, the maximum thickness 800 nm of the overlapping electrode layer 24, the maximum thickness 6 μm of the organic material layer 25 and the maximum thickness 300 nm of the second buffer layer 26 are selected, the thickness H2 of the film layers in the bending area A3 may be calculated to be equal to 7.4 μm which is smaller than the thickness H1 of the film layers in the bending area B3 of the driving substrate as shown in FIG. 1, and therefore, in the embodiment of the present disclosure, the thickness of the film layers in the bending area A3 may be reduced. The maximum bending strain of the inorganic film layer in the bending area A3 is 2.47% smaller than the safety bending strain 2.52% under the condition that the bending radius of the bending area A3 is 50 μm.

In addition, the rigid substrate 21 is made of a rigid material which may be specifically any one of quartz, glass, silicon dioxide, silicon, plastic and polymethyl methacrylate. The debonding layer (DBL) 22 is made of polyimide or polyimide modified material, and the thickness of the debonding layer 22 is 30 nm to 100 nm.

As shown in FIG. 2 and FIG. 3, the wiring layer 27 includes a first wiring layer 271 formed on the second buffer layer 26 in the component disposing area A1 and the circuit board binding area A2; wherein the first wiring layer 271 in the component disposing area A1 is connected to one end of the overlapping electrode layer 24 through a first via hole passing through the second buffer layer 26 and the organic material layer 25; and the first wiring layer 271 in the circuit board binding area A2 is connected to the other end of the overlapping electrode layer 24 through a second via hole passing through the second buffer layer 26 and the organic material layer 25.

Wherein, the first wiring layer 271 is made of copper, and the thickness of the first wiring layer 271 is 0.6 μm to 1.2 μm.

As shown in FIG. 2 and FIG. 3, the driving substrate located in the component disposing area A1 and the circuit board binding area A2 further includes a planarization layer 28 covering the first wiring layer 271 and the second buffer layer 26 located in the component disposing area A1 and the circuit board binding area A2.

Specifically, the planarization layer 28 is only located in the component disposing area A1 and the circuit board binding area A2, and no planarization layer 28 is disposed in the bending area A3; and the planarization layer 28 is made of a resin material, the thickness of the planarization layer 28 is smaller than or equal to 6 μm, and the planarization layer 28 is used for realizing the planarization of the driving substrate.

In an alternative implementation manner of the present disclosure, as shown in FIG. 3, the driving substrate located in the component disposing area A1 and the circuit board binding area A2 further includes a third buffer layer 29 covering the planarization layer 28, and the first wiring layer 271 is partially exposed out of the planarization layer 28 and the third buffer layer 29.

Wherein, the third buffer layer 29 is made of silicon nitride, silicon oxide or silicon oxynitride, and the thickness of the third buffer layer 29 is 50 nm to 300 nm.

Specifically, the first wiring layer 271 in the component disposing area A1 and the circuit board binding area A2 is partially exposed out of the planarization layer 28 and the third buffer layer 29. During actual manufacture, a first opening N1 passing through the third buffer layer 29 and the planarization layer 28 is formed in a position corresponding to the first wiring layer 271 in the component disposing area A1, and the first opening N1 is used for connecting light emitting components to the first wiring layer 271 later; and a second opening N2 passing through the third buffer layer 29 and the planarization layer 28 is formed in a position corresponding to the first wiring layer 271 in the circuit board binding area A2, and the second opening N2 is used for connecting a circuit board to the first wiring layer 271 later.

In another alternative embodiment of the present disclosure, as shown in FIG. 2, the wiring layer 27 further includes a second wiring layer 272 formed on the planarization layer 28 in the component disposing area A1, and the second wiring layer 272 is connected to the first wiring layer 271 through a third via hole passing through the planarization layer 28; and the driving substrate located in the component disposing area A1 and the circuit board binding area A2 further includes a third buffer layer 29 covering the planarization layer 28 and the second wiring layer 272, and the second wiring layer 272 is partially exposed out of the third buffer layer 29.

Wherein, the second wiring layer 272 is made of copper, and the thickness of the second wiring layer 272 is 0.6 μm to 1.2 μm. The third buffer layer 29 is made of silicon nitride, silicon oxide or silicon oxynitride, and the thickness of the third buffer layer 29 is 50 nm to 300 nm.

During actual manufacture, a third opening N3 passing through the third buffer layer 29 is formed in a position corresponding to the second wiring layer 272 in the component disposing area A1, and the third opening N3 is used for connecting light emitting components to the second wiring layer 272 later. An orthographic projection of the third opening N3 on the rigid substrate 21 may overlap with an orthographic projection of a top surface (the surface of the side, away from the first wiring layer 271, of the second wiring layer 272) of the second wiring layer 272 on the rigid substrate 21, at the moment, the top surface of the second wiring layer 272 is not provided with the third buffer layer 29, and the third buffer layer 29 only covers a side wall of the second wiring layer 272 and the planarization layer 28; or the orthographic projection of the third opening N3 on the rigid substrate 21 may be located within the orthographic projection of the top surface of the second wiring layer 272 on the rigid substrate 21, at the moment, the third buffer layer 29 covers the side wall of the second wiring layer 272 and the planarization layer 28, in addition, the third buffer layer 29 is further disposed in a partial area on the top surface of the second wiring layer 272. The third buffer layer 29 may be used for protecting the side wall of the second wiring layer 272.

In addition, the first wiring layer 271 in the circuit board binding area A2 is partially exposed out of the planarization layer 28 and the third buffer layer 29. During actual manufacture, a second opening N2 passing through the third buffer layer 29 and the planarization layer 28 is formed in a position corresponding to the first wiring layer 271 in the circuit board binding area A2, and the second opening N2 is used for connecting a circuit board and the first wiring layer 271.

It should be noted that the wiring layer 27 shown in FIG. 2 includes a first wiring layer 271 and a second wiring layer 272 in the component disposing area A1 and only includes the first wiring layer 271 in the circuit board binding area A2; and the wiring layer 27 shown in FIG. 3 only includes the first wiring layer 271 in the component disposing area A1 and the circuit board binding area A2. During actual manufacture, whether the wiring layer 27 shown in FIG. 2 or the wiring layer 27 shown in FIG. 3 is selected is determined according to circuit layout in the component disposing area A1, and when the circuit layout in the component disposing area A1 cannot be achieved by one-layer wiring, two-layer wiring shown in FIG. 2 needs to be set.

As shown in FIG. 3, the driving substrate located in the bending area A3 further includes the debonding layer 22, and the debonding layer 22 is located at a side, away from the overlaying electrode layer 24, of the first buffer layer 23.

During actual manufacture, it is possible that the rigid substrate 21 in the bending area A3 is only removed, and the debonding layer 22 in the bending area A3 is remained.

It should be noted that, for the driving substrate shown in FIG. 2, both the rigid substrate 21 and the debonding layer 22 in the bending area A3 are removed; and for the driving substrate shown in FIG. 3, the rigid substrate 21 in the bending area A3 is only removed.

When there is still the debonding layer 22 in the bending area A3, the film layers in the bending area A3 of the driving substrate include the debonding layer 22, the first buffer layer 23, the overlapping electrode layer 24, the organic material layer 25 and the second buffer layer 26, the maximum thickness of the debonding layer 22 is 100 nm, and if the maximum thickness of each film layer in the bending area A3 is selected, at the moment, the thickness H2 of the film layers in the bending area A3 is 7.5 μm which is also smaller than the thickness H1 of the film layers in the bending area B3 of the driving substrate shown in FIG. 1.

As shown in FIG. 3, the driving substrate located in the bending area A3 further includes the third buffer layer 29, and the third buffer layer 29 is located at a side, away from the organic material layer 25, of the second buffer layer 26.

During actual manufacture, the third buffer layer 29 in the bending area A3 may not be removed.

It should be noted that, for the driving substrate shown in FIG. 2, the third buffer layer 29 in the bending area A3 is removed, and the third buffer layer 29 is only disposed in the component disposing area A1 and the circuit board binding area A2; and for the driving substrate shown in FIG. 3, the third buffer layer 29 is disposed in the component disposing area A1, the circuit board binding area A2 and the bending area A3.

When there is still the third buffer layer 29 in the bending area A3, the film layers in the bending area A3 of the driving substrate include the first buffer layer 23, the overlapping electrode layer 24, the organic material layer 25, the second buffer layer 26 and the third buffer layer 29, the maximum thickness of the third buffer layer 29 is 300 nm, and if the maximum thickness of each film layer in the bending area A3 is selected, at the moment, the thickness H2 of the film layers in the bending area A3 is 7.7 μm which is also smaller than the thickness H1 of the film layers in the bending area B3 of the driving substrate shown in FIG. 1. When there are still the debonding layer 22 and the third buffer layer 29 in the bending area A3, the film layers in the bending area A3 of the driving substrate include the debonding layer 22, the first buffer layer 23, the overlapping electrode layer 24, the organic material layer 25, the second buffer layer 26 and the third buffer layer 29, the maximum thickness of the debonding layer 22 is 100 nm, the maximum thickness of the third buffer layer 29 is 300 nm, and if the maximum thickness of each film layer in the bending area A3 is selected, at the moment, the thickness H2 of the film layers in the bending area A3 is 7.8 μm which is also smaller than the thickness H1 of the film layers in the bending area B3 of the driving substrate shown in FIG. 1.

In an embodiment of the present disclosure, when the bending area A3 is in a non-bent state, the rigid substrate 21 located in the component disposing area A1 and the rigid substrate 21 located in the circuit board binding area A2 are disposed along a same horizontal plane; and when the bending area A3 is in a bent state, the rigid substrate 21 located in the component disposing area A1 is bonded to the rigid substrate 21 located in the circuit board binding area A2.

Further, when the bending area A3 is in the bent state, a bonding layer is disposed on a contact surface of the component disposing area A1 and the bending area A3 and a contact surface of the circuit board binding area A2 and the bending area A3 and between the rigid substrate 21 located in the component disposing area A1 and the rigid substrate 21 located in the circuit board binding area A2.

Wherein, the bonding layer is made of a UV (Ultraviolet Rays) curable adhesive which has a viscosity of 5000 cps to 8000 cps.

During actual manufacture, after the rigid substrate 21 in the bending area A3 is removed, the side, away from the debonding layer 22, of the rigid substrate 21 in the component disposing area A1 and/or the circuit board binding area A2, the side wall, facing the bending area A3, of the rigid substrate 21 in the component disposing area A1 and the side wall, facing the bending area A3, of the rigid substrate 21 in the circuit board binding area A2 are coated with a bonding layer, and then, the bending area A3 is bent to ensure that the rigid substrate 21 in the component disposing area A1 is bonded to the rigid substrate 21 in the circuit board binding area A2, at the moment, the bonding layer is disposed on the contact surface of the component disposing area A1 and the bending area A3 and the contact surface of the circuit board binding area A2 and the bending area A3 and between the rigid substrate 21 located in the component disposing area A1 and the rigid substrate 21 located in the circuit board binding area A2 and is used for fixing and bonding the component disposing area A1 to the circuit board binding area A2 after the bending area A3 is bent.

In the embodiment of the present disclosure, by only disposing the first buffer layer, the overlapping electrode layer, the organic material layer and the second buffer layer in the bending area, the number of the film layers in the bending area is reduced, so that the thickness of the film layers in the bending area is reduced, then, the maximum bending strain of the film layers in the bending area is reduced, it is ensured that fractures or cracks do not occur in the film layers in the bending area, the quality of the driving substrate is improved, and the bending reliability of the bending area is guaranteed.

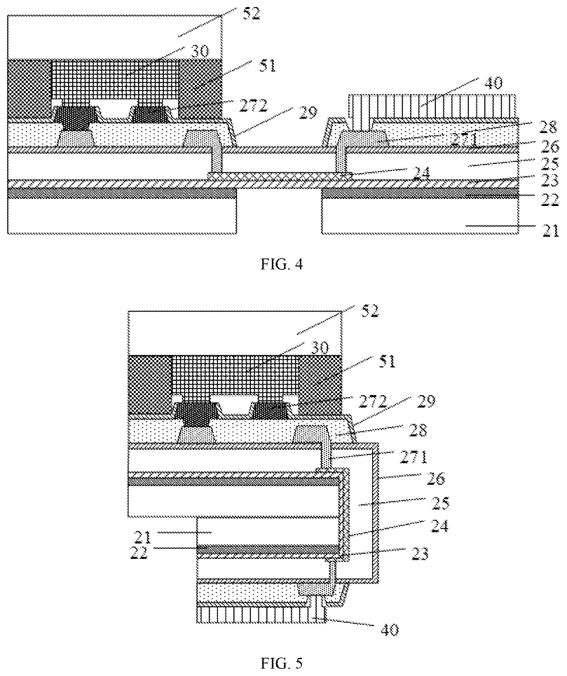

FIG. 4 shows a schematic diagram of a structure of a light emitting apparatus in a non-bent state in a bending area in an embodiment of the present disclosure. FIG. 5 shows a schematic diagram of a structure of a light emitting apparatus in a bent state in a bending area in an embodiment of the present disclosure.

As shown in FIG. 4 and FIG. 5, the light emitting apparatus includes a circuit board 40, light emitting components 30 and the driving substrate in above-mentioned exemplary embodiment, wherein the light emitting components 30 are connected to the wiring layer 27 in the component disposing area A1, and the circuit board 40 is connected to the wiring layer 27 in the circuit board binding area A2.

In the embodiment of the present disclosure, the light emitting apparatus is manufactured by using the driving substrate as shown in FIG. 2, so that a connection relationship between the circuit board 40 and the driving substrate and a connection relationship between the light emitting components 30 and the driving substrate are described. Therefore, for the wiring layer 27 in FIG. 4 and FIG. 5, the component disposing area A1 includes the first wiring layer 271 and the second wiring layer 272, the circuit board binding area A2 only includes the first wiring layer 271, and therefore, the light emitting components 30 are connected to the second wiring layer 272 through the third opening N3 (the position of the third opening N3 is specifically shown in FIG. 2) passing through the third buffer layer 29, and the circuit board 40 is connected to the first wiring layer 271 through the second opening N2 (the position of the second opening N2 is specifically shown in FIG. 2) passing through the third buffer layer 29 and the planarization layer 28.

Of course, the light emitting apparatus may also be manufactured by using the driving substrate as shown in FIG. 3, at the moment, in the component disposing area A1 and the circuit board binding area A2, the wiring layer 27 only includes the first wiring layer 271, and therefore, the light emitting components 30 are connected to the first wiring layer 271 through the first opening N1 (the position of the first opening N1 is specifically shown in FIG. 3) passing through the third buffer layer 29 and the planarization layer 28, and the circuit board 40 is also connected to the first wiring layer 271 through the second opening N2 (the position of the second opening N2 is specifically shown in FIG. 3) passing through the third buffer layer 29 and the planarization layer 28.

Seen from FIG. 4 and FIG. 5, when the bending area A3 is in a non-bent state, the rigid substrate 21 located in the component disposing area A1 and the rigid substrate 21 located in the circuit board binding area A2 are disposed along the same horizontal plane; and when the bending area A3 is in a bent state, the rigid substrate 21 located in the component disposing area A1 is bonded to the rigid substrate 21 located in the circuit board binding area A2.

In addition, the light emitting apparatus further includes a first adhesive layer 52 disposed at a side, away from the rigid substrate 21, of the light emitting components 30 and a second adhesive layer 51 disposed on a side wall of the light emitting components 30. Wherein the first adhesive layer 52 is a white adhesive and is used for protecting the light emitting components 30, and the second adhesive layer 51 is a black adhesive and is used for avoiding the cross color of rays emitted by all the light emitting components 30.

During actual application, if the light emitting components 30 are micro-LEDs, a plurality of micro-LED arrays may be directly used as display pixels of a display unit, and thus, the light emitting apparatus may be used as the display unit; and the plurality of the micro-LED arrays may also be used as direct-type backlight sources to supply rays to a display panel on a light emitting side thereof.

In addition, the specific description for the driving substrate may refer to the description in the forgoing exemplary embodiments, the detailed description thereof is omitted herein.

In the embodiment of the present disclosure, by only disposing the first buffer layer, the overlapping electrode layer, the organic material layer and the second buffer layer in the bending area of the driving substrate, the number of the film layers in the bending area is reduced, so that the thickness of the film layers in the bending area is reduced, then, the maximum bending strain of the film layers in the bending area is reduced, it is ensured that fractures or cracks do not occur in the film layers in the bending area, the quality of the driving substrate is improved, and the bending reliability of the bending area is guaranteed.

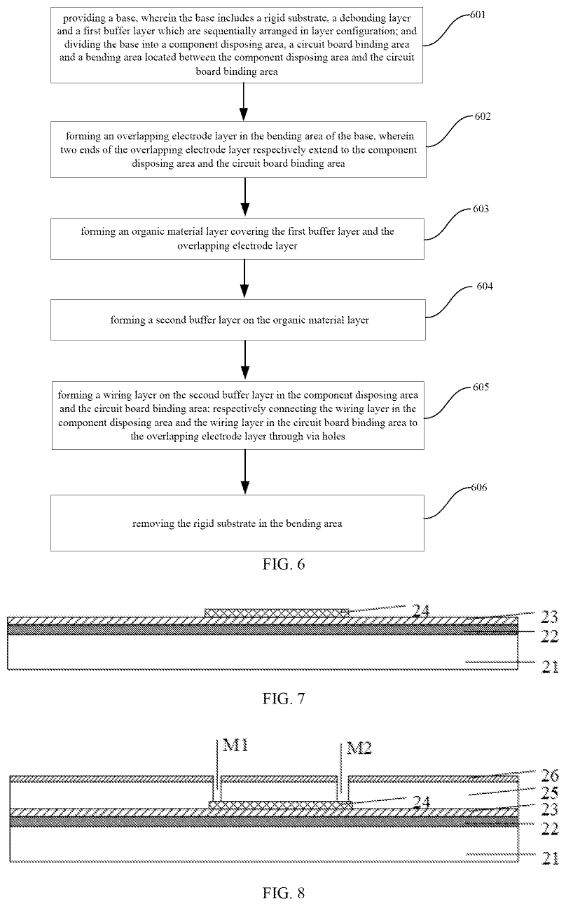

FIG. 6 shows a flow chart of a manufacturing method for a light emitting apparatus in an embodiment of the present disclosure. Specifically, the manufacturing method may include the following steps:

step 601, a base is provided, wherein the base includes a rigid substrate, a debonding layer and a first buffer layer which are sequentially arranged in layer configuration; and the base is divided into a component disposing area, a circuit board binding area and a bending area located between the component disposing area and the circuit board binding area.

In an embodiment of the present disclosure, as shown in FIG. 7, a base is provided, wherein the base includes a rigid substrate 21, a debonding layer 22 and a first buffer layer 23 which are sequentially arranged in layer configuration; and the base is divided into a component disposing area A1, a circuit board binding area A2 and a bending area A3 located between the component disposing area A1 and the circuit board binding area A2.

Specifically, a debonding layer 22 is formed on the rigid substrate 21, and the rigid substrate 21 is made of a rigid material which may be specifically any one of quartz, glass, silicon dioxide, silicon, plastic and poly-methyl methacrylate. The debonding layer 22 is made of polyimide or polyimide modified material, and the thickness of the debonding layer 22 is 30 nm to 100 nm. Then, a first buffer layer 23 is deposited on the debonding layer 22, the first buffer layer 23 is made of silicon nitride, silicon oxide or silicon oxynitride, and the thickness of the first buffer layer 23 is 50 nm to 300 nm.

At the moment, the rigid substrate 21 and the debonding layer 22 are distributed in the component disposing area A1, the circuit board binding area A2 and the bending area A3.

Step 602, an overlapping electrode layer is formed in the bending area of the base, wherein two ends of the overlapping electrode layer respectively extend to the component disposing area and the circuit board binding area.

In an embodiment of the present disclosure, as shown in FIG. 7, an overlapping electrode layer 24 is formed in the bending area A3 of the base. Specifically, the overlapping electrode layer 24 is formed on the first buffer layer 23 in the bending area A3 by adopting a patterning process, and two ends of the overlapping electrode layer 24 respectively extend to the component disposing area A1 and the circuit board binding area A2.

Wherein, in view of demands on the bending performance and stable voltage of the overlapping electrode layer 24, the overlapping electrode layer 24 may be made of at least one of copper, molybdenum, titanium and aluminum. Specifically, the thickness of the overlapping electrode layer 24 is 300 nm to 800 nm. For example, the overlapping electrode layer 24 may have a titanium/aluminum/titanium structure arranged in layer configuration.

It should be noted that the patterning process in the embodiment of the present disclosure includes thin film deposition, photoresist coating, using mask exposure, development, etching, photoresist removal and other processes.

Step 603, an organic material layer covering the first buffer layer and the overlapping electrode layer is formed.

In an embodiment of the present disclosure, after the overlapping electrode layer 24 is formed in the bending area A3 of the base, as shown in FIG. 8, an organic material layer 25 covering the first buffer layer 23 and the overlapping electrode layer 24 is formed.

Wherein, the organic material layer 25 is made of PI, the thickness of the organic material layer 25 is smaller than or equal to 6 μm, and specifically, the organic material layer 25 may be formed by adopting a coating process.

Step 604, a second buffer layer is formed on the organic material layer.

In an embodiment of the present disclosure, as shown in FIG. 8, after the organic material layer 25 covering the first buffer layer 23 and the overlapping electrode layer 24 is formed, a second buffer layer 26 is formed on the organic material layer 25.

Specifically, the second buffer layer 26 may be formed on the organic material layer 25 by adopting a chemical vapor deposition (CVD) process, the second buffer layer 26 is made of silicon nitride, silicon oxide or silicon oxynitride, and the thickness of the second buffer layer 26 is 50 nm to 300 nm.

Step 605, a wiring layer is formed on the second buffer layer in the component disposing area and the circuit board binding area; the wiring layer in the component disposing area and the wiring layer in the circuit board binding area are respectively connected to the overlapping electrode layer through via holes.

In an embodiment of the present disclosure, after the second buffer layer 26 is formed on the organic material layer 25, a wiring layer 27 is formed on the second buffer layer 26 in the component disposing area A1 and the circuit board binding area A2.

In the following, the wiring layer 27 including a first wiring layer 271 and a second wiring layer 272 in the component disposing area A1 and only including the first wiring layer 271 in the circuit board binding area A2 is taken as an example to describe the specific manufacturing process:

in an alternative embodiments of the present disclosure, the step 605 may specifically include sub-step S6051 and sub-step S6052:

sub-step S6051: a first via hole and a second via hole passing through the second buffer layer and the organic material layer are respectively formed in the component disposing area and the circuit board binding area; and

sub-step S6052: a first wiring layer is formed on the second buffer layer in the component disposing area and the circuit board binding area; and the first wiring layers are respectively connected to the overlapping electrode layer through the first via hole and the second via hole.

As shown in FIG. 8, after the second buffer layer 26 is formed on the organic material layer 25, a first via hole M1 passing through the second buffer layer 26 and the organic material layer 25 is formed in the component disposing area A1, and a second via hole M2 passing through the second buffer layer 26 and the organic material layer 25 is formed in the circuit board binding area A2. Specifically, the second buffer layer 26 is coated with a photoresist, the photoresist on the second buffer layer 26 is exposed by using a mask, development is performed after exposure to obtain a photoresist removal area, the second buffer layer 26 in the photoresist removal area is etched to form the via holes passing through the second buffer layer 26, then, the organic material layer 25 in the via holes passing through the second buffer layer 26 is exposed by taking the second buffer layer 26 as the mask, and then, development is performed, so that the first via hole M1 and the second via hole M2 passing through the second buffer layer 26 and the organic material layer 25 may be formed.

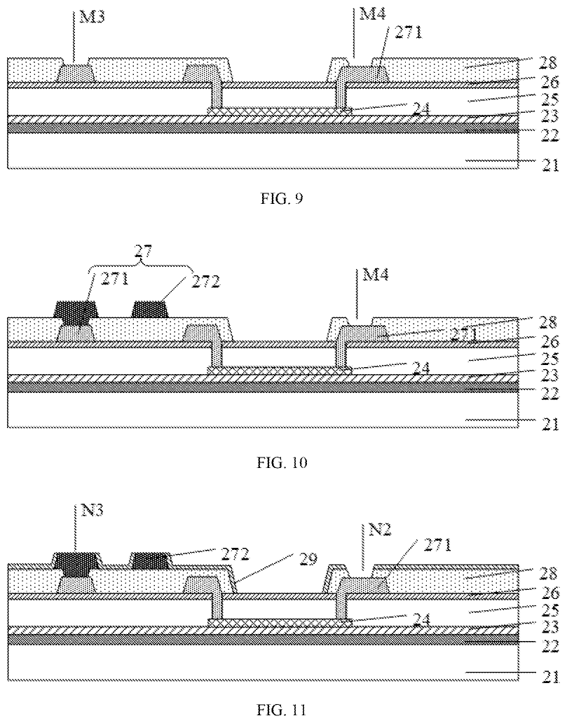

As shown in FIG. 9, a first wiring layer 271 is formed on the second buffer layer 26 in the component disposing area A1 and the circuit board binding area A2, the first wiring layer 271 in the component disposing area A1 is connected to one end of the overlapping electrode layer 24 through the first via hole M1 passing through the second buffer layer 26 and the organic material layer 25, and the first wiring layer 271 in the circuit board binding area A2 is connected to the other end of the overlapping electrode layer 24 through a second via hole M2 passing through the second buffer layer 26 and the organic material layer 25.

Further, after the sub-step S6052, the step 605 further includes sub-step S6053, sub-step S6054 and sub-step S6055:

sub-step S6053, a planarization layer covering the first wiring layer and the second buffer layer located in the component disposing area and the circuit board binding area is formed;

sub-step S6054, a second wiring layer is formed on the planarization layer in the component disposing area; and the second wiring layer is connected to the first wiring layer through a third via hole passing through the planarization layer; and

sub-step S6055, a third buffer layer covering the planarization layer and the second wiring layer is formed; and the second wiring layer is partially exposed out of the third buffer layer.

As shown in FIG. 9, after the first wiring layer 271 is formed on the second buffer layer 26 in the component disposing area A1 and the circuit board binding area A2, a planarization layer 28 covering the first wiring layer 271 and the second buffer layer 26 located in the component disposing area A1 and the circuit board binding area A2 is formed.

Specifically, firstly, the component disposing area A1, the circuit board binding area A2 and the bending area A3 are coated with a layer of planarization layer material covering the first wiring layer 271 and the second buffer layer 26, a mask is adopted to expose and develop the planarization layer material, the planarization layer material in the bending area A3 is removed, a third via hole M3 passing through the planarization layer 28 is formed in a position corresponding to the first wiring layer 271 in the component disposing area A1, and a fourth via hole M4 passing through the planarization layer 28 is also formed in a position corresponding to the first wiring layer 271 in the circuit board binding area A2.

As shown in FIG. 10, a second wiring layer 272 is formed on the planarization layer 28 in the component disposing area A1 by adopting a patterning process, and the second wiring layer 272 is connected to the first wiring layer 271 through the third via hole M3 passing through the planarization layer 28.

As shown in FIG. 11, a third buffer layer 29 covering the planarization layer 28 and the second wiring layer 272 is formed; and the second wiring layer 272 is partially exposed out of the third buffer layer 29. Specifically, firstly, a third buffer film covering the planarization layer 28, the second wiring layer 272 and the second buffer layer 26 is formed and is coated with a photoresist, a mask is adopted to expose the photoresist on the third buffer film, development is performed after exposure to obtain a photoresist removal area. The photoresist removal area includes positions where the second wiring layers 272 in the bending area A3 and the component disposing area A1 are located, and a position where the first wiring layer 271 in the circuit board binding area A2 is located. The third buffer film in the photoresist removal area is etched to obtain a third buffer layer 29. Therefore, the third buffer layer 29 in the bending area A3 is removed, a third opening N3 passing through the third buffer layer 29 is formed in a position corresponding to the second wiring layer 272, and a second opening N2 passing through the third buffer layer 29 and the planarization layer 28 is formed in a position corresponding to the first wiring layer 271 in the circuit board binding area A2.

It should be noted that when the third buffer film is formed, the fourth via hole M4 passing through the planarization layer 28 and formed in the position corresponding to the first wiring layer 271 in the circuit board binding area A2 may be filled with the third buffer film, and when the third buffer film is etched later, the third buffer film in the fourth via hole M4 may be removed, and thus, the second opening N2 passing through the third buffer layer 29 and the planarization layer 28 is formed.

Wherein, the first wiring layer 271 is made of copper, and the thickness of the first wiring layer 271 is 0.6 μm to 1.2 μm. The planarization layer 28 is made of a resin material, and the thickness of the planarization layer 28 is smaller than or equal to 6 μm. The second wiring layer 272 is made of copper, and the thickness of the second wiring layer 272 is 0.6 μm to 1.2 μm. The third buffer layer 29 is made of silicon nitride, silicon oxide or silicon oxynitride, and the thickness of the third buffer layer 29 is 50 nm to 300 nm.

Step 606, the rigid substrate in the bending area is removed.

In an embodiment of the present disclosure, after all the film layers are formed on the second buffer layer 26 in the component disposing area A1 and the circuit board binding area A2, the rigid substrate 21 in the bending area A3 is removed.

Specifically, the step 606 includes: the rigid substrate and the debonding layer in the bending area are removed by adopting a laser lift-off process.

The laser lift off (LLO) process is adopted to cut the rigid substrate 21 in the bending area A3. In the process of cutting the rigid substrate 21, the debonding layer 22 in the bending area A3 may be carbonized, and thus, the laser lift off process may be adopted to remove the rigid substrate 21 and the debonding layer 22 in the bending area A3 at the same time.

Of course, a cutter wheel cutting process may also be adopted to cut the rigid substrate 21 in the bending area A3, so that the rigid substrate 21 in the bending area A3 is removed. After the rigid substrate 21 in the bending area A3 is removed, the laser lift off process or other processes may be adopted to remove the debonding layer 22 in the bending area A3, of course, the debonding layer 22 in the bending area A3 may not be removed.

It should be noted that after the rigid substrate 21 in the bending area A3 is removed, the bending area A3 may be bent, then, light emitting components 30 are bound and connected to the wiring layer 27 in the component disposing area A1, and a circuit board 40 is bound and connected to the wiring layer 27 in the circuit board binding area A2, that is, a manner of binding after bending is adopted.

Of course, a manner of bending after binding may also be adopted. Compared with the manner of binding after bending, the manner of bending after binding avoids a complicated procedure for machining on the back of a driving substrate and is simpler and more reliable in process.

The manufacturing process of the light emitting apparatus will be described later with specific to the manner of binding after bending, and therefore, before the step 606, the method further includes step S61 and S62:

step S61, the light emitting components are connected to the second wiring layer in the component disposing area, and the circuit board is connected to the first wiring layer in the circuit board binding area; and

step S62, a first adhesive layer is formed at a side, away from the rigid substrate, of the light emitting components, and a second adhesive layer is formed on a side wall of the light emitting components.

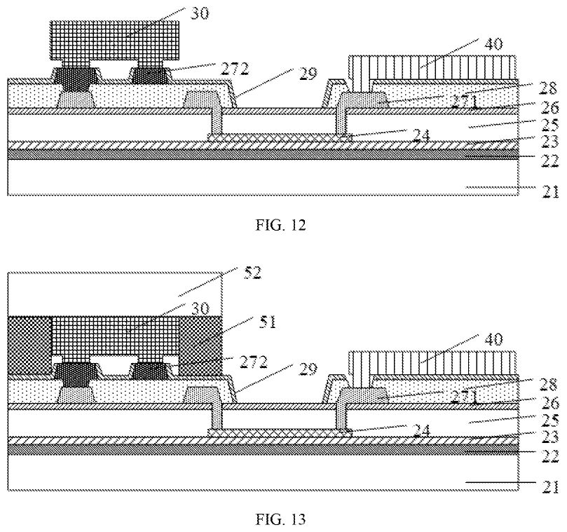

In an embodiment of the present disclosure, as shown in FIG. 12, after the third buffer layer 29 covering the planarization layer 28 and the second wiring layer 272 is formed, the light emitting components 30 are bound and connected to the second wiring layer 272 in the component disposing area A1, and the circuit board 40 is bound and connected to the first wiring layer 271 in the circuit board binding area A2. Specifically, the exposed second wiring layer 272 is coated with tin paste on the position of the third opening N3 passing through the third buffer layer 29, and the exposed first wiring layer 271 is coated with tin paste on the position of the second opening N2 passing through the third buffer layer 29 and the planarization layer 28; then, pins of the light emitting components 30 are in contact with the tin paste on the second wiring layer 272 through the third opening N3, and the circuit board 40 is in contact with the tin paste on the first wiring layer 271 through the second opening N2; and finally, the coated tin paste is heated to be thawed and is then cooled, so that the light emitting components 30 are connected to the second wiring layer 272 in the component disposing area A1, and the circuit board 40 is connected to the first wiring layer 271 in the circuit board binding area A2.

As shown in FIG. 13, after the light emitting components 30 and the circuit board 40 are bound to the driving substrate, the side, away from the rigid substrate 21, of the light emitting components 30 is coated with a first adhesive layer 52, a side wall of the light emitting components 30 is coated with a second adhesive layer 51, the first adhesive layer 52 is a white adhesive, and the second adhesive layer 51 is a black adhesive.

Then, the rigid substrate 21 and the debonding layer 22 in the bending area A3 are removed to obtain a structure as shown in FIG. 4. After the step 606, the method further includes step S63 and step S64:

step S63, a bonding layer is disposed on the side, away from the debonding layer, of the rigid substrate, the side wall, facing the bending area, of the rigid substrate in the component disposing area and the side wall, facing the bending area, of the rigid substrate in the circuit board binding area; and

step S64, the bending area is bent to ensure that the rigid substrate in the component disposing area is bonded to the rigid substrate in the circuit board binding area.

In an embodiment of the present disclosure, after the rigid substrate 21 and the debonding layer 22 in the bending area A3 are removed, the side, away from the debonding layer 22, of the rigid substrate 21 of the component disposing area A1 and/or the circuit board binding area A2, the side wall, facing the bending area A3, of the rigid substrate 21 in the component disposing area A1 and the side wall, facing the bending area A3, of the rigid substrate 21 in the circuit board binding area A2 is coated with a bonding layer, and then, the bending area A3 is bent to ensure that the rigid substrate 21 in the component disposing area A1 is bonded to the rigid substrate 21 in the circuit board binding area A2, so that the structure as shown in FIG. 5 is obtained.

At the moment, the bonding layer is disposed on the contact surface of the component disposing area A1 and the bending area A3 and the contact surface of the circuit board binding area A2 and the bending area A3 and between the rigid substrate 21 located in the component disposing area A1 and the rigid substrate 21 located in the circuit board binding area A2 and is used for fixing and bonding the component disposing area A1 to the circuit board binding area A2 after the bending area A3 is bent.

In the embodiment of the present disclosure, by only disposing the first buffer layer, the overlapping electrode layer, the organic material layer and the second buffer layer in the bending area, the number of the film layers in the bending area is reduced, so that the thickness of the film layers in the bending area is reduced, then, the maximum bending strain of the film layers in the bending area is reduced, it is ensured that fractures or cracks do not occur in the film layers in the bending area, the quality of the driving substrate is improved, and the bending reliability of the bending area is guaranteed.

For the purpose of simple description, all the foregoing embodiments of the method have been described as a series of combinations of actions for convenience of the descriptions, but those skilled in the art shall appreciate that the present disclosure will not be limited to the described order of the actions because some of the steps can be performed in a different order or concurrently according to the present disclosure. Secondly, those skilled in the art shall further appreciate that the embodiments described in the description are preferred embodiments, and the related actions and modules are not necessarily used for implementing the present disclosure.

All the embodiments in the present description are described in a progressive manner, the emphasis in the embodiments will focus on differences from other embodiments, and the same or similar parts among all the embodiments may refer to each other.

Finally, it should be further noted that relational terms such as first and second described herein are only used to distinguish one entity or operation from another one, but do not necessarily require or imply the presence of any such actual relationship or order between these entities or operations. Moreover, terms “includes”, “including” or any other variants thereof are intended to cover non-excludable inclusion, so that a process, method, commodity or equipment including a series of elements not only includes those elements, but also includes other elements not listed clearly, or further includes inherent elements of the process, method, commodity or equipment. Under the condition that no more limitations are provided, elements defined by the word “including a . . . . . . ” do not exclude other same elements further existing in the process, method, commodity or equipment including the elements.

As above, the driving substrate, the light emitting apparatus and the manufacturing method therefor provided by the present disclosure have been introduced in detail. Specific examples are applied in the present disclosure to describe the principle and implementation manners of the present disclosure. The descriptions of the foregoing embodiments are merely intended to help understand the method and concept of the present disclosure. Meanwhile, those of ordinary skill in the art may, based on the concept of the present disclosure, make modifications with respect to the specific implementation manners and the application scope. In conclusion, the content of this description shall not be understood as a limitation on the present disclosure.

1. A driving substrate, comprising a component disposing area, a circuit board binding area and a bending area located between the component disposing area and the circuit board binding area; wherein,
the driving substrate located in the component disposing area and the circuit board binding area comprises a rigid substrate, a debonding layer, a first buffer layer, an organic material layer, a second buffer layer and a wiring layer which are sequentially arranged in layer configuration;
the driving substrate located in the bending area comprises the first buffer layer, an overlapping electrode layer, the organic material layer and the second buffer layer which are sequentially arranged in layer configuration;
wherein two ends of the overlapping electrode layer respectively extend to the component disposing area and the circuit board binding area, and the wiring layer of the component disposing area and the wiring layer of the circuit board binding area are respectively connected to the overlapping electrode layer through via holes.

2. The driving substrate according to claim 1, wherein the wiring layer comprises a first wiring layer formed on the second buffer layer in the component disposing area and the circuit board binding area;
wherein the first wiring layer in the component disposing area is connected to one end of the overlapping electrode layer through a first via hole passing through the second buffer layer and the organic material layer; and the first wiring layer in the circuit board binding area is connected to the other end of the overlapping electrode layer through a second via hole passing through the second buffer layer and the organic material layer.

3. The driving substrate according to claim 2, wherein the driving substrate located in the component disposing area and the circuit board binding area further comprises a planarization layer covering the first wiring layer and the second buffer layer located in the component disposing area and the circuit board binding area.

4. The driving substrate according to claim 3, wherein the driving substrate located in the component disposing area and the circuit board binding area further comprises a third buffer layer covering the planarization layer, and the first wiring layer is partially exposed out of the planarization layer and the third buffer layer.

5. The driving substrate according to claim 4, wherein a first opening passing through the third buffer layer and the planarization layer is formed in a position corresponding to the first wiring layer of the component disposing area, and the first opening is configured to connect light emitting components to the first wiring layer; and
a second opening passing through the third buffer layer and the planarization layer is formed in a position corresponding to the first wiring layer of the circuit board binding area, and the second opening is configured to connect a circuit board to the first wiring layer.

6. The driving substrate according to claim 3, wherein the wiring layer further comprises a second wiring layer formed on the planarization layer of the component disposing area, and the second wiring layer is connected to the first wiring layer through a third via hole passing through the planarization layer; and
the driving substrate located in the component disposing area and the circuit board binding area further comprises a third buffer layer covering the planarization layer and the second wiring layer, and the second wiring layer is partially exposed out of the third buffer layer.

7. The driving substrate according to claim 6, wherein a third opening passing through the third buffer layer is formed in a position corresponding to the second wiring layer in the component disposing area, and the third opening is configured to connect the light emitting components to the second wiring layer.

8. The driving substrate according to claim 7, wherein an orthographic projection of the third opening on the rigid substrate overlaps with an orthographic projection of a top surface of the second wiring layer on the rigid substrate; or
the orthographic projection of the third opening on the rigid substrate is located within the orthographic projection of the top surface of the second wiring layer on the rigid substrate;
wherein the top surface of the second wiring layer is a surface of the second wiring layer away from the first wiring layer.

9. The driving substrate according to claim 1, wherein the driving substrate located in the bending area further comprises the debonding layer, and the debonding layer is located at a side, away from the overlaying electrode layer, of the first buffer layer.

10. The driving substrate according to claim 4 or 6, wherein the driving substrate located in the bending area further comprises the third buffer layer, and the third buffer layer is located at a side, away from the organic material layer, of the second buffer layer.

11. The driving substrate according to claim 1, wherein when the bending area is in a non-bent state, the rigid substrate located in the component disposing area and the rigid substrate located in the circuit board binding area are disposed along a same horizontal plane; and
when the bending area is in a bent state, the rigid substrate located in the component disposing area is bonded to the rigid substrate located in the circuit board binding area.

12. (canceled)

13. The driving substrate according to claim 1, wherein the debonding layer is made of polyimide or polyimide modified material; and a thickness of the debonding layer is 30 nm to 100 nm;
the overlapping electrode layer is made of at least one of copper, molybdenum, titanium and aluminum; and a thickness of the overlapping electrode layer is 300 nm to 800 nm;
a thickness of the first buffer layer is 50 nm to 300 nm; a thickness of the organic material layer is smaller than or equal to 6 μm; and a thickness of the second buffer layer is 50 nm to 300 nm.

14. (canceled)

15. (canceled)

16. A light emitting apparatus, wherein the light emitting apparatus comprises a circuit board, light emitting components and the driving substrate according to claim 1, the light emitting components are connected to the wiring layer in the component disposing area, and the circuit board is connected to the wiring layer in the circuit board binding area.

17. The light emitting apparatus according to claim 16, wherein the light emitting apparatus further comprises a first adhesive layer disposed at a side, away from the rigid substrate, of the light emitting components and a second adhesive layer disposed on a side wall of the light emitting components;
wherein the first adhesive layer is configured to protect the light emitting components, and the second adhesive layer is configured to avoid a cross color of rays emitted by the light emitting components.

18. A manufacturing method for a light emitting apparatus, wherein the method comprises:
providing a base, wherein the base comprises a rigid substrate, a debonding layer and a first buffer layer which are sequentially arranged in layer configuration; and dividing the base into a component disposing area, a circuit board binding area and a bending area located between the component disposing area and the circuit board binding area;
forming an overlapping electrode layer in the bending area of the base, wherein two ends of the overlapping electrode layer respectively extend to the component disposing area and the circuit board binding area;
forming an organic material layer covering the first buffer layer and the overlapping electrode layer;
forming a second buffer layer on the organic material layer;
forming a wiring layer on the second buffer layer in the component disposing area and the circuit board binding area; respectively connecting the wiring layer in the component disposing area and the wiring layer in the circuit board binding area to the overlapping electrode layer through via holes; and
removing the rigid substrate in the bending area.

19. The method according to claim 18, wherein the step of forming the wiring layer on the second buffer layer in the component disposing area and the circuit board binding area comprises:
respectively forming a first via hole and a second via hole passing through the second buffer layer and the organic material layer in the component disposing area and the circuit board binding area; and
forming a first wiring layer on the second buffer layer in the component disposing area and the circuit board binding area; and respectively connecting the first wiring layers to the overlapping electrode layer through the first via hole and the second via hole.

20. The method according to claim 19, wherein after the step of forming the first wiring layer on the second buffer layer in the component disposing area and the circuit board binding area, the method further comprises:
forming a planarization layer covering the first wiring layer and the second buffer layer located in the component disposing area and the circuit board binding area;
forming a second wiring layer on the planarization layer in the component disposing area; and connecting the second wiring layer to the first wiring layer through a third via hole passing through the planarization layer; and
forming a third buffer layer covering the planarization layer and the second wiring layer; and partially exposing the second wiring layer out of the third buffer layer.

21. The method according to claim 20, wherein before the step of removing the rigid substrate in the bending area, the method further comprises:
connecting light emitting components to the second wiring layer in the component disposing area, and connecting a circuit board to the first wiring layer in the circuit board binding area; and
forming a first adhesive layer at a side, away from the rigid substrate, of the light emitting components, and forming a second adhesive layer on a side wall of the light emitting components.

22. The method according to claim 18, wherein the step of removing the rigid substrate in the bending area comprises:
removing the rigid substrate and the debonding layer in the bending area by adopting a laser lift off process.

23. The method according to claim 18, wherein after the step of removing the rigid substrate in the bending area, the method further comprises:
disposing a bonding layer at a side, away from the debonding layer, of the rigid substrate, the side wall, facing the bending area, of the rigid substrate in the component disposing area and the side wall, facing the bending area, of the rigid substrate in the circuit board binding area; and
bending the bending area to ensure that the rigid substrate in the component disposing area is bonded to the rigid substrate in the circuit board binding area.
